(19) United States
(12) Patent Application Publication
(10) Pub. No.: US 2011/0049692 A1
(43) Pub. Date: Mar. 3, 2011

(54) CONNECTION DEVICE BEWTEEN TRANSISTOR AND LEAD FRAME

(75) Inventor: Chung Hsing TZU, Taipei County (TW)

(73) Assignee: Great Team Backend Foundry, Inc., Bristish Virgin Islands (GB)

(21) Appl. No.: 12/859,268

(22) Filed: Aug. 19, 2010

Related U.S. Application Data
(60) Provisional application No. 61/237,757, filed on Aug. 28, 2009.

(51) Int. Cl. H01L 23/495

(52) U.S. Cl. 257/676; 257/E23.031

(57) ABSTRACT

A connection device includes a transistor, a lead frame, a first connection member and a second connection member. The signal is electronically connected between the transistor and the lead frame by the first and second connection members. The second connection member is located above the first connection member so as to increase the communication area for the signals and reduce the resistance between the transistor and the lead frame.

### FIELD OF THE INVENTION

The present invention relates to a connection device, and more particularly, to a connection device connected between a transistor and a lead from so as to increase the rate of communication and reduce the resistance.

### BACKGROUND OF THE INVENTION

A conventional way for connecting transistors is shown in FIGS. 1 to 3, and generally includes a connection member 3 connected one of more chips 1 and a lead frame 2 so as to achieve the purpose of communication for signals. The material for making the connection member 3 generally includes gold, copper and aluminum, which can be made in the form of gold wires, copper wires and aluminum wires. In order to avoid from separation of damage during packaging processes, the connection member 3 needs more bonding area 11 when bonded on the transistors 1 and the lead frame 2. However, the gold wires, copper wires and aluminum wires or pressing copper strip is so thin such that the communication area 31 for the signals is restricted and less than the bonding areas 12, 21 on the transistor 1 and the lead frame 2. This generates significant resistance which deters the communication rate and becomes one of the main concerns in this business.

In order to improve the shortcomings mentioned due to high resistance, the present invention provides a second connection member which increases the communication area and the rate of communication by reducing the resistance.

### SUMMARY OF THE INVENTION

The present invention relates to a connection device which comprises a transistor on which a first bonding area is defined, a lead frame on which a second bonding area is defined, a first connection member having two ends thereof bonded on the first and second bonding areas, and a second connection member. The second connection member has two bonding spots on two ends thereof and the two bonding spots are respectively bonded directly on the transistor and on the lead frame or a position of the first connection member wherein the position is not in contact with the transistor and the lead frame or.

The primary object of the present invention is to provide a connection device that increases the communication area and reduces the resistance between the transistor and the lead frame.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 shows the first conventional connection member connected between the transistor and the lead frame;

FIG. 2 shows the second conventional connection member connected between the transistor and the lead frame;

FIG. 3 shows the third conventional connection member connected between the transistor and the lead frame;

FIG. 4 shows the connection device of the present invention connected between the transistor and the lead frame;

FIG. 5 shows the first embodiment of the connection device of the present invention connected between the transistor and the lead frame;

FIG. 6 shows the second embodiment of the connection device of the present invention connected between the transistor and the lead frame;

FIG. 7 shows the third embodiment of the connection device of the present invention connected between the transistor and the lead frame;

FIG. 8 shows the fourth embodiment of the connection device of the present invention connected between the transistor and the lead frame;

FIG. 9 shows the fifth embodiment of the connection device of the present invention connected between the transistor and the lead frame, and

FIG. 10 shows the sixth embodiment of the connection device of the present invention connected between the transistor and the lead frame.

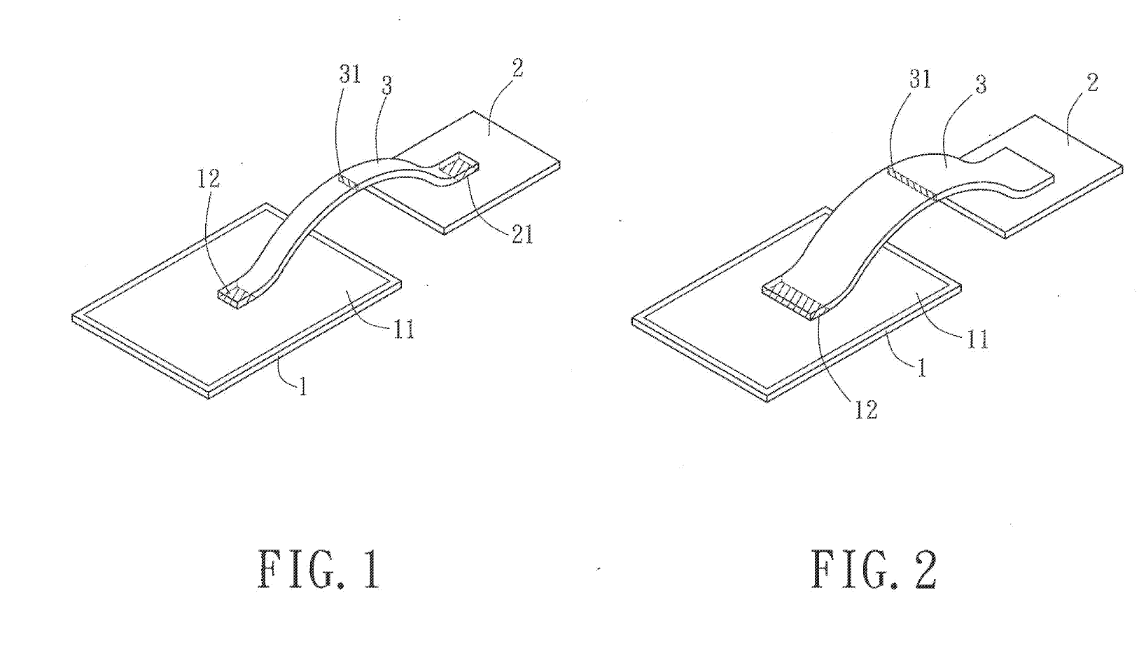

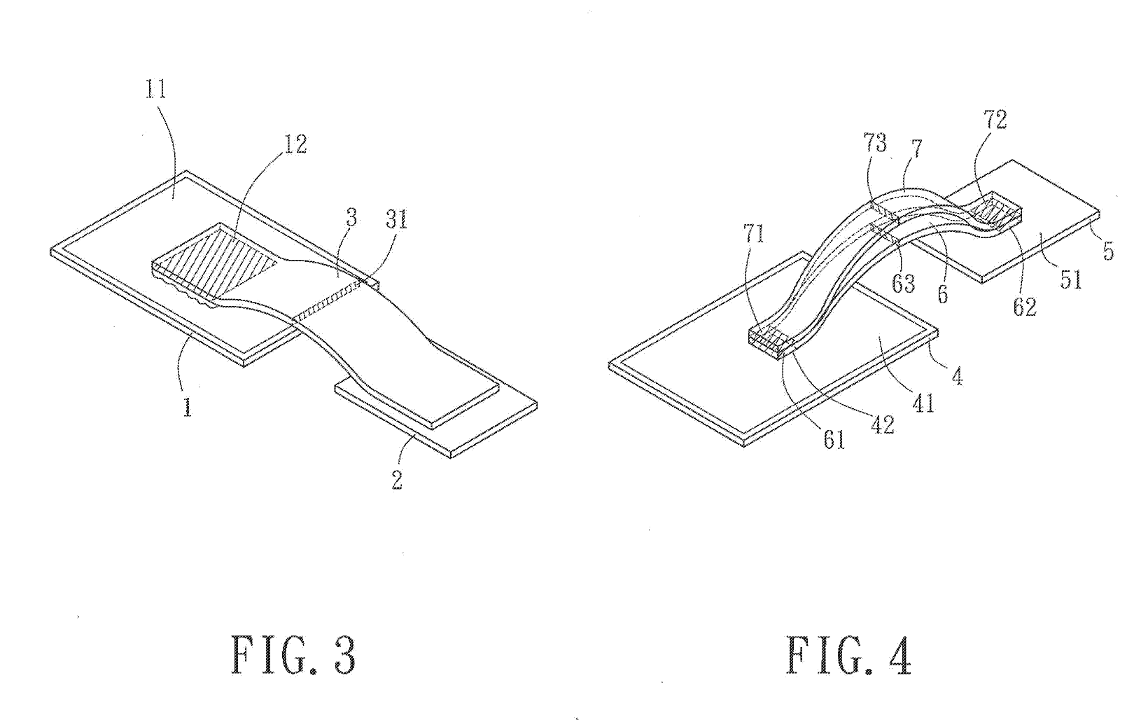

### DETAILED DESCRIPTION OF THE PREFERRED EMBODIMENT

Referring to FIG. 4, the present invention provides at least one transistor 4, at least one lead frame 5, at least one first connection member 6 and at least one second connection member 7.

The transistor 4 includes a first connection area 41 at a pre-chosen area thereof and the first connection member 6 has a first bonding spot 61 on end thereof and which is bonded on the first connection area 41 and the bonding area called the first bonding area 42.

The lead frame 5 includes a second bonding area 51 at a pre-chosen area thereof and the first connection member 6 has a second bonding spot 62 on the other end thereof and which is bonded on the second bonding area 51.

The first connection member 6 is made of gold, copper or aluminum, and made in a form of wire, band or pressing strip. Therefore, the first connection member 6 can be made in the form of gold wire, copper wire, aluminum wire, aluminum band and pressing copper strip. After the first bonding spot 61 is bonded on the first bonding area 42 of the transistor 4 and the second bonding spot 62 is bonded on the second bonding area 51 of the lead frame 5, the cross section of the first connection member 6 is called the communication area 63 which allows the signals to pass therethrough.

The second connection member 7 is made of gold, copper or aluminum, and made in a form of wire, band or pressing strip. Therefore, the second connection member 7 can be made in the form of gold wire, copper wire, aluminum wire, aluminum band and pressing copper strip.

The second connection member 7 has a third bonding spot 71 and a fourth bonding spot 72 on two ends thereof. The third bonding spot 71 is bonded on a position of the first connection member 6 wherein the position is not in contact with the transistor 4. The fourth bonding spot 72 is bonded on a position of the first connection member 6 wherein the position is not in contact with the lead frame 5. By this way, the area for communication is increased while the resistance between the transistor and the lead frame 5 is reduced, such that the rate for communication is increased.

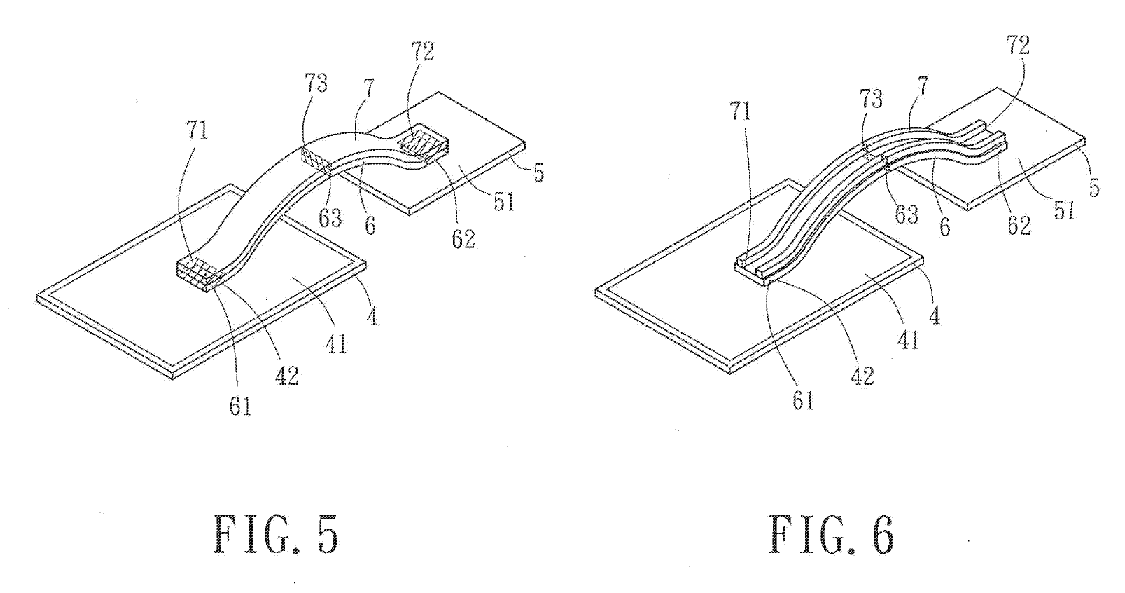

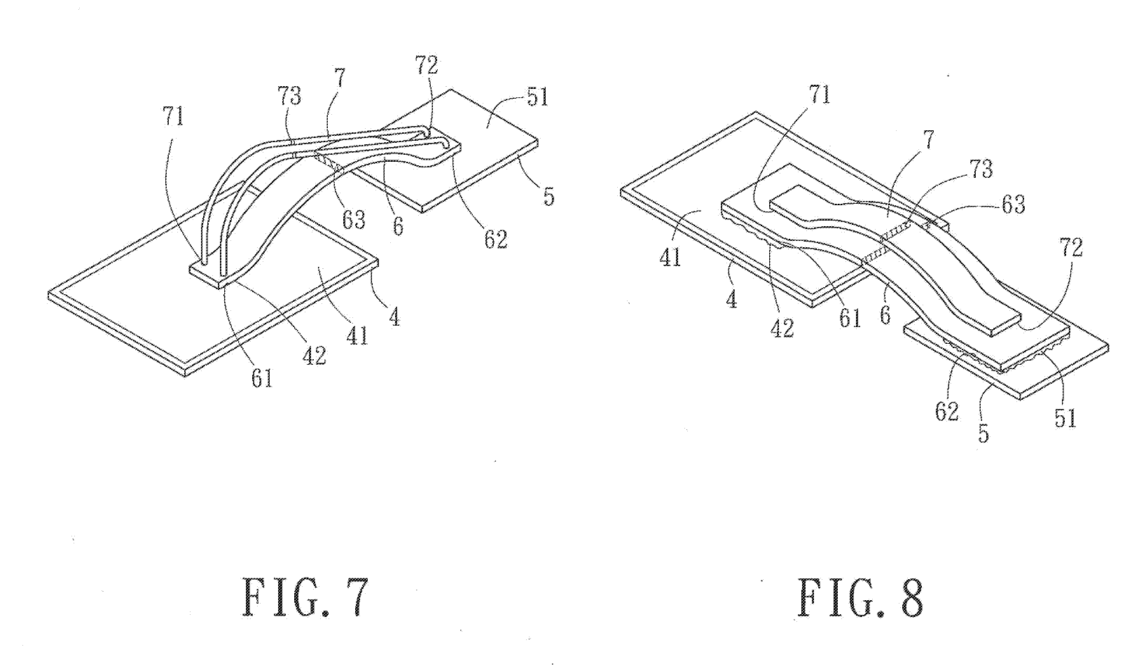

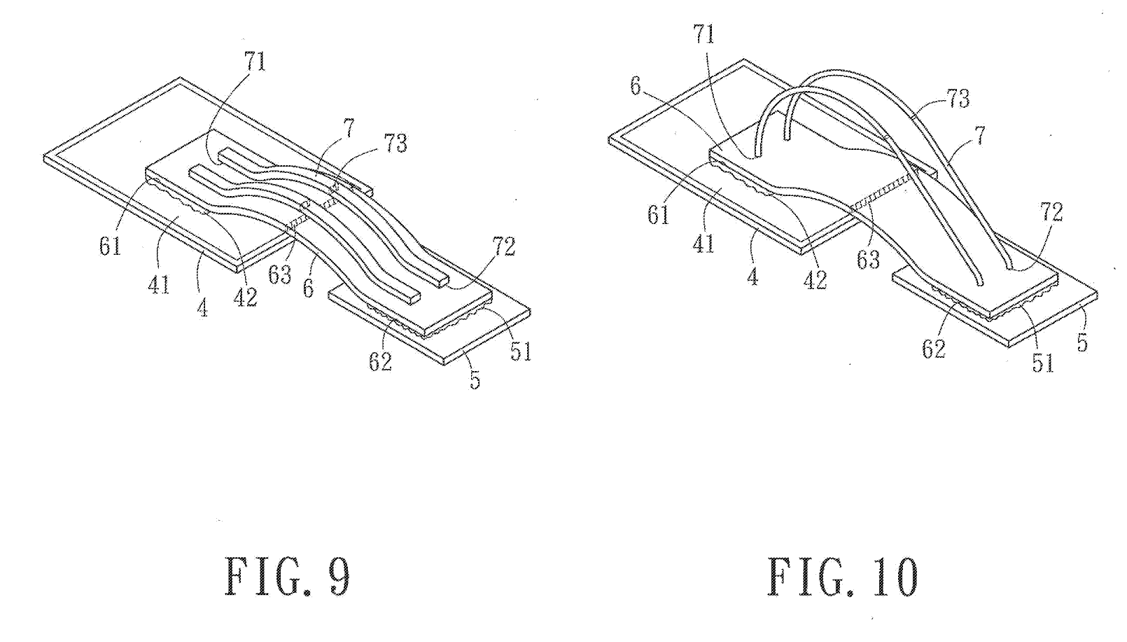

FIGS. 5 to 10 different forms of the first and second connection members 6, 7 connected between the transistor 4 and the lead frame 5. FIG. 5 shows that the first connection member 6 is in the form of a pressing copper strip and the second connection member 7 is in the form of a pressing copper strip. FIG. 6 that shows that the first connection member 6 is in the form of a band and the second connection member 7 is in the form of an aluminum wire. FIG. 7 that shows the first connection member 6 is in the form of a strip and the second connection member 7 is in the form of a gold wire or copper wire. FIG. 8 shows that the first connection member 6 is in the form of a pressing copper strip and the second connection member 7 is in the form of a band. FIG. 9 shows that the first connection member 6 is in the form of a pressing copper strip and the second connection member 7 is in the form of an aluminum wire. FIG. 10 shows that the first connection member 6 is in the form of a pressing copper strip and the second connection member 7 is in the form of a gold wire or copper wire.

The shape or number of the first and second connection members 6, 7 can be varied according to needs and the number of layer that the second connection member 7 is located above the first connection member 6 can also be increased according to the packing area and height.

While we have shown and described the embodiment in accordance with the present invention, it should be clear to those skilled in the art that further embodiments may be made without departing from the scope of the present invention.

What is claimed is:

1. A connection device comprising:
at least one transistor on which a first bonding area is defined;
at least one lead frame on which a second bonding area is defined;
at least one first connection member having a first bonding spot and a second bonding spot on two ends thereof, the first bonding spot being bonded on the first bonding area of the at least one transistor, the second bonding spot being bonded on the second bonding area of the at least one lead frame, and
at least one second connection member having a third bonding spot and a fourth bonding spot on two ends thereof, the third bonding spot being bonded on a position of the at least one first connection member wherein the position is not in contact with the at least one transistor, the fourth bonding spot being bonded on a position of the at least one first connection member wherein the position is not in contact with the at least one lead frame.

2. The device as claimed in claim 1, wherein the at least one first connection member is made of gold, copper or aluminum.

3. The device as claimed in claim 1, wherein the at least one first connection member is made in a form of wire, band or pressing strip.

4. The device as claimed in claim 1, wherein the at least one second connection member is made of gold, copper or aluminum.

5. The device as claimed in claim 1, wherein the at least one second connection member is made in a form of wire, band or pressing strip.

6. A connection device comprising:
at least one transistor on which a first bonding area is defined;
at least one lead frame on which a second bonding area is defined;
at least one first connection member having a first bonding spot and a second bonding spot on two ends thereof, the first bonding spot being bonded on the first bonding area of the at least one transistor, the second bonding spot being bonded on the second bonding area of the at least one lead frame, and
at least one second connection member having a third bonding spot and a fourth bonding spot on two ends thereof, the third bonding spot being bonded on the first bonding area of the at least one transistor, the fourth bonding spot being bonded on the second bonding area of the at least one lead frame.

7. The device as claimed in claim 6, wherein the at least one first connection member is made of gold, copper or aluminum.

8. The device as claimed in claim 6, wherein the at least one first connection member is made in a form of wire, band or pressing strip.

9. The device as claimed in claim 6, wherein the at least one second connection member is made of gold, copper or aluminum.

10. The device as claimed in claim 6, wherein the at least one second connection member is made in a form of wire, band or pressing strip.
